(19) United States
(12) Patent Application Publication
(10) Pub. No.: US 2019/0304682 A1
(43) Pub. Date: Oct. 3, 2019

(54) DIELECTRIC THIN-FILM ELEMENT AND ELECTRONIC COMPONENT

(71) Applicant: TDK CORPORATION, Tokyo (JP)

(72) Inventor: Yusuke SATO, Tokyo (JP)

(73) Assignee: TDK CORPORATION, Tokyo (JP)

(21) Appl. No.: 16/352,020

(22) Filed: Mar. 13, 2019

(30) Foreign Application Priority Data
Mar. 27, 2018 (JP) 2018-060721

(51) Int. Cl. H01G 4/08; H01G 4/33; H01G 4/005; H01L 49/02

(52) U.S. Cl. CPC H01G 4/08; H01L 28/60; H01G 4/005; H01G 4/33

(57) ABSTRACT

The present disclosure provides a dielectric thin-film element and an electronic component, in which a dielectric constant is improved. A thin-film capacitor has a lamination structure including a lower electrode, a dielectric thin film that is laminated on the lower electrode and includes BaTi₂O₅ as a main composition, and an upper electrode that is laminated on the dielectric thin film. The inventors have newly found that a high relative permittivity can be obtained when BaTi₂O₅ is in a form of a thin film and a {001} plane of BaTi₂O₅ in the dielectric thin film is oriented in a lamination direction of the lamination structure.

### CROSS-REFERENCE TO RELATED APPLICATIONS

This application is based upon and claims the benefit of priority from Japanese Patent Application No. 2018-060721, filed on 27 Mar. 2018, the entire contents of which are incorporated herein by reference.

### TECHNICAL FIELD

The present disclosure relates to a dielectric thin-film element and an electronic component.

### BACKGROUND

In the related art, BaTiO₃ (barium titanate) is widely known as a dielectric material of dielectric thin-film elements, such as thin-film capacitors and static capacitance thin-film sensors.
[Patent Literature 1] Japanese Unexamined Patent Publication No. 2004-210601
[Non-Patent Literature 1] Junjun Wang and two others, “Preparation of ferroelectric BaTi2O5 thin films on Pt(111)/Ti/SiO2/Si substrates by pulsed laser deposition”, Journal of Alloys and Compounds, 2012, Vol. 512, pp. 140-143
[Non-Patent Literature 2] Takaya Akashi and two others, “Preparation of BaTi2O5 Single Crystal by a Floating Zone Method”, Materials Transactions, 2003, Vol. 44, No. 4, pp. 802-804

### SUMMARY

Since BaTiO₃ described above has a relatively low Curie point, it is difficult to realize sufficient temperature stability. For example, in a mass manufacturing process and the like, when a BaTiO₃ thin film is repetitively exposed to a high temperature environment and a low temperature environment, the film quality is deteriorated due to domain structure phase transition.

BaTi₂O₅ (barium dititanate, having a Curie point of approximately 470° C.) is known as a dielectric material having a higher Curie point than BaTiO₃. Patent Literature 1 discloses a technology of utilizing BaTi₂O₅ as a dielectric in a form of a plate-shaped piece of single crystal.

The inventors have repeatedly researched the technology of utilizing BaTi₂O₅ as a dielectric. As a result, the inventors have newly found a technology in which a dielectric constant can be significantly improved.

The present disclosure provides a dielectric thin-film element and an electronic component, in which a dielectric constant is improved.

According to an embodiment of the present disclosure, there is provided a dielectric thin-film element having a lamination structure including a first thin-film electrode, a dielectric thin film that is laminated on the first thin-film electrode and includes BaTi₂O₅ as a main composition, and a second thin-film electrode that is laminated on the dielectric thin film. A {001} plane of BaTi₂O₅ in the dielectric thin film is oriented in a lamination direction of the lamination structure.

The inventors have newly found that a high dielectric constant can be obtained when BaTi₂O₅ is in a form of a thin film and the {001} plane of BaTi₂O₅ is oriented in the lamination direction of the lamination structure.

In the dielectric thin-film element according to the embodiment, in the dielectric thin film, a gap between (020) planes of BaTi₂O₅ present within a plane perpendicular to the lamination direction may be 1.967 Å or larger.

The dielectric thin-film element according to the embodiment may further include a buffer layer that is interposed between the first thin-film electrode and the dielectric thin film. The buffer layer may be made of BaTiO₃.

In the dielectric thin-film element according to the embodiment, a mole ratio Ti/Ba of Ti to Ba included in the dielectric thin film may be within a range of 1.8 to 2.2.

In the dielectric thin-film element according to the embodiment, a part of Ba of BaTi₂O₅ in the dielectric thin film may be replaced with at least one element of the group consisting of Mg, Ca, and Sr.

In the dielectric thin-film element according to the embodiment, a part of Ti of BaTi₂O₅ in the dielectric thin film may be replaced with Zr.

According to another embodiment of the present disclosure, there is provided an electronic component including the dielectric thin-film element described above.

### BRIEF DESCRIPTION OF THE DRAWINGS

FIG. 1 is a view illustrating a lamination structure of a thin-film capacitor according to an embodiment of the present disclosure.

FIG. 2 is a view schematically illustrating a crystal structure of BaTi₂O₅ in the dielectric thin film in FIG. 1.

FIG. 3 is a view illustrating the lamination structure of the thin-film capacitor according to an aspect different from that in FIG. 1.

FIG. 4 is a table showing experimental results according to Examples of the present disclosure.

FIG. 5 is a table showing experimental results according to Examples of the present disclosure.

FIG. 6 is a table showing experimental results according to Examples of the present disclosure.

FIG. 7 is a table showing experimental results according to Examples of the present disclosure.

### DETAILED DESCRIPTION

Hereinafter, various embodiments and Examples will be described with reference to the drawings. The same reference signs are applied to the same or corresponding parts in each of the drawings, and duplicated description will be omitted.

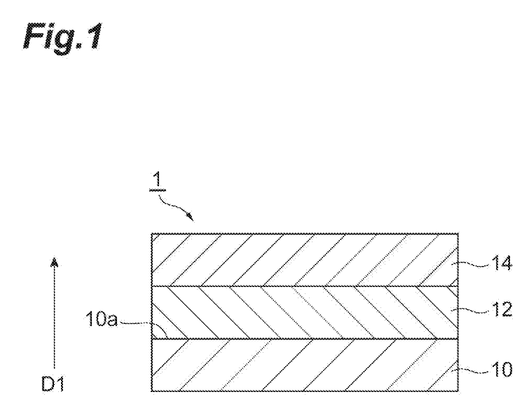

FIG. 1 illustrates a thin-film capacitor 1, which is one of dielectric thin-film elements. As illustrated in FIG. 1, the thin-film capacitor 1 has a lamination structure including a lower electrode 10 (first thin-film electrode), a dielectric thin film 12, and an upper electrode 14 (second thin-film electrode). In order from below in FIG. 1, the lower electrode 10, the dielectric thin film 12, and the upper electrode 14 are sequentially laminated.

Both the lower electrode 10 and the upper electrode 14 are thin-film shaped electrodes. The lower electrode 10 and the upper electrode 14 face each other in a lamination direction D1 of the thin-film capacitor 1. For example, the lower electrode 10 and the upper electrode 14 are made of a conductive material such as Pt, Ir, or Ag. The lower electrode 10 and the upper electrode 14 have a thickness of approximately 500 nm, for example.

The dielectric thin film 12 is a thin film including BaTi₂O₅, which is one of dielectric materials, as a main composition. The thickness of the dielectric thin film 12 may be within a range of 50 to 2,000 nm or may be within a range of 50 to 1,000 nm. As an example, the thickness of the dielectric thin film 12 is 700 nm.

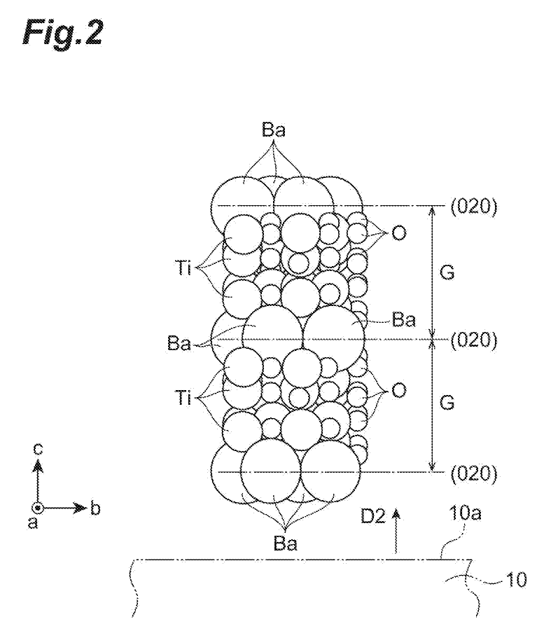

The dielectric thin film 12 is an oriented growth thin film (so-called oriented film), and BaTi₂O₅ in the dielectric thin film 12 forms columnar crystal as illustrated in FIG. 2. The columnar crystal of BaTi₂O₅ extends in a normal direction D2 on a main surface 10a of the lower electrode 10.

In this case, a {001} plane of BaTi₂O₅ is oriented in the normal direction D2. The normal direction D2 is a direction parallel to the lamination direction D1 of the thin-film capacitor 1 and is also a direction parallel to an applying direction of a voltage applied to a portion between the lower electrode 10 and the upper electrode 14.

In addition, a {010} plane of BaTi₂O₅ is present in a direction perpendicular to the normal direction D2. Moreover, a (020) crystal axis (axis b in FIG. 2) in a spontaneous polarization direction of BaTi₂O₅ is present within a plane perpendicular to the normal direction D2. A Ba layer made of Ba atoms is present in a (020) plane of BaTi₂O₅. A plurality of Ba layers are arranged in the normal direction D2 in BaTi₂O₅ in the dielectric thin film 12, and a TiO₆ structure having three layers (three kinds) is interposed between Ba layers adjacent to each other. In the dielectric thin film 12, a gap G between the Ba layers (that is, a (020) plane gap) is 1.967 Å or larger.

In addition, in the dielectric thin film 12, a mole ratio of Ti to Ba (Ti/Ba mole ratio) is within a range of 1.8 to 2.2. When the Ti/Ba mole ratio deviates from the foregoing range, heterogenous phases are generated, so that the dielectric constant is reduced, or pressure resistance or thermal shock resistance intensity is reduced sometimes. For example, when the Ti/Ba mole ratio is less than 1.8, BaTiO₃ is likely to be generated, and when the Ti/Ba mole ratio exceeds 2.2, BaTi₄O₉ or the like is likely to be generated.

A part of Ba of BaTi₂O₅ which is a main composition of the dielectric thin film 12 may be replaced with at least one element of the group consisting of Mg, Ca, and Sr, and a part of Ti thereof may be replaced with Zr. Even if these are replaced, the dielectric constant of the dielectric thin film 12 is not reduced substantially, and a dielectric constant to the same extent can be realized.

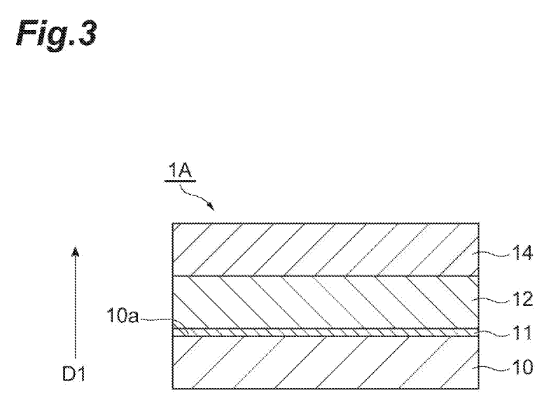

In place of the thin-film capacitor 1, a thin-film capacitor 1A can be adopted as illustrated in FIG. 3. The thin-film capacitor 1A differs from the thin-film capacitor 1 in including a buffer layer 11 which is interposed between the lower electrode 10 and the dielectric thin film 12, and the configuration is otherwise the same as or equivalent to that of the thin-film capacitor 1.

The buffer layer 11 is constituted of a BaTiO₃ (111) oriented film. The thickness of the buffer layer 11 may be within a range of 0.1 to 1 nm and is 0.5 nm, as an example. The buffer layer 11 may be a multi-layer structure made of different materials.

According to the dielectric thin film 12 of the thin-film capacitor 1 or 1A described above, the inventors have newly found that it is possible to obtain a higher dielectric constant than in single crystal BaTi₂O₅ in a plate-shaped piece according to the technologies in the related art. That is, in the dielectric thin film 12 of the thin-film capacitor 1 or 1A, the {001} plane of BaTi₂O₅ is oriented in the normal direction D2, and the spontaneous polarization direction ((020) crystal axis direction) of BaTi₂O₅ is present within a plane perpendicular to the normal direction D2 of the main surface 10a of the lower electrode 10. Therefore, BaTi₂O₅ having a high relative permittivity can be obtained. As the reason for this, it is assumed that the dielectric constant is higher in a direction perpendicular to the polarization direction than in the polarization direction, and ferroelectricity is applied to the TiO₆ structure due to in-plane stress or interaction of the lower electrode 10. In addition, improvement of the dielectric constant can be realized by mounting the thin-film capacitor 1 or 1A in an electronic component.

### Examples

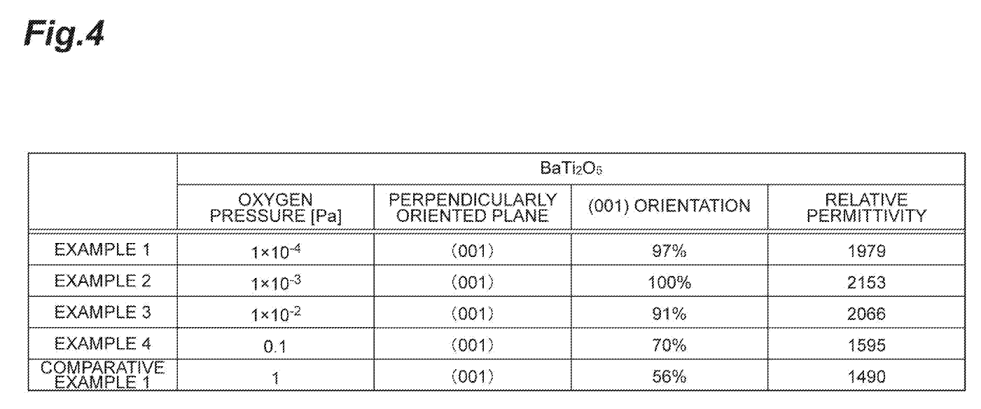

Hereinafter, details and results of experiments performed by the inventors will be described with reference to tables in FIGS. 4 to 7. The following method of producing a dielectric thin film is just an example, and the disclosure is not limited to the following manufacturing method.

In the present example, BaTi₂O₅ was deposited on a Si substrate with SiO₂ thermal oxide film, Ti oxide film, and Pt(111) oriented film provided thereon, constituting a dielectric thin film. A pulsed laser deposition (PLD) method was used for depositing BaTi₂O₅. Methods other than the PLD method for depositing BaTi₂O₅ can be used, such as a sputtering method.

Hereinafter, a procedure of BaTi₂O₅ deposition using the PLD method will be described.

In the PLD method, a target consisting of a predetermined composition was used, and a BaTi₂O₅ target was used for depositing BaTi₂O₅ according to the present Example. When the BaTi₂O₅ target was produced, as starting materials, for example, base powders of barium carbonate and titanium oxide were prepared. Each of these starting materials was weighed to have a desired Ti/Ba mole ratio (for example, a Ti/Ba mole ratio within the range of 1.8 to 2.2) in composition analysis after deposition. Base powder which becomes oxide through heating, such as carbonate and oxalate, may be used as a starting material.

Next, the weighed starting materials were sufficiently mixed in an organic solvent or in the water for 5 to 20 hours by using a ball mill, for example. After the mixed starting materials were sufficiently dried, they were temporarily calcined at a temperature within a range of 900° C. to 1,100° C. for approximately 1 to 3 hours. Subsequently, this temporarily calcined material was crushed in an organic solvent or in the water for 5 to 30 hours by using a ball mill or the like. Moreover, the crushed temporarily calcined material was dried again and was granulated by adding a binder solution consisting of PVA, for example, and a granulated powder was obtained. This granulated powder was press-molded, and a block-shaped molded body was obtained.

The block-shaped molded body was heated to a temperature within a range of 300° C. to 600° C. for approximately 2 to 4 hours, and the binder component was volatilized. Subsequently, as primary calcination, the molded body was calcined at a temperature within a range of 1,100° C. to 1,250° C. for approximately 2 to 4 hours. The rate of temperature increase and the rate of temperature decrease in the molded body at the time of this primary calcination could be adjusted to approximately 50 to 300° C./hours, for example. In this manner, a BaTi₂O₅ target could be obtained. The average grain size of BaTi₂O₅ crystal grains included in this target may be within a range of approximately 1 to 20 μm, for example.

In depositing BaTi₂O₅ by the PLD method, first, the target and the depositing substance were disposed to face each other inside a vacuum chamber. In the present Example, the BaTi₂O₅ target obtained as described above was used as a target, and a substrate and the lower electrode 10 were used as the depositing substance. While the depositing substance was heated, the target was irradiated with a pulsed laser, ions and the like generated due to explosive vaporization were deposited on the depositing substance, and a BaTi₂O₅ thin film was formed.

When a BaTi₂O₅ thin film is obtained, the temperature of the depositing substance (deposition temperature) need only be within a range of 300° C. to 800° C., for example. An oxygen partial pressure inside the vacuum chamber need only be within a range of 10⁻⁴ to 50 Pa, for example.

Other than those described above, examples of parameters to be controlled by the PLD method include a laser oscillation frequency, and a distance between the substrate and the target. A desired BaTi₂O₅ thin film can be obtained by controlling these parameters. For example, the laser oscillation frequency affects the degree of orientation of the BaTi₂O₅ thin film. When the laser oscillation frequency is 10 Hz or lower, the degree of orientation of the BaTi₂O₅ thin film is likely to be increased.

The orientation plane azimuth, the degree of orientation, the lattice plane gap, and the like of the BaTi₂O₅ thin film were measured by using an X-ray diffraction (XRD) device (manufactured by Rigaku Corporation: Smart Lab). First, in out-of-plane 2θ-θ measurement, when measurement was performed within a range of 20=15° to 70°, the peak derived from the BaTi₂O₅ thin film was confirmed. When Cu—Kα rays having a wavelength of 1.541 Å were used for X-rays, a (002) peak of the BaTi₂O₅ thin film was observed to have approximately 20=19.35°. The degree of a (001) orientation was calculated from the azimuth peak intensity of each plane obtained from the XRD spectrum, by using a Lotgering method. In addition, in in-plane 2θ_{χ}-ϕ measurement, measurement was performed within a range of 2θ_{χ}=15° to 50°, and the plane gap thereof was measured from a (020) peak angle of the BaTi₂O₅ thin film appearing to have approximately 2θ_{χ}=46.10°.

The dielectric thin-film element for measurement was prepared by forming Ag film on a BaTi₂O₅ thin film as an upper electrode 14 by using an evaporation method. The Ag electrode was a dot electrode having a circular shape. Its diameter was 100 μm, and its thickness was 100 nm.

When the relative permittivity of the dielectric thin-film element was obtained, first, a measurement probe was brought into contact with the upper electrode 14 and an exposed part electrically connected to a lower electrode, and the static capacitance was measured by using an LCR meter (manufactured by Keysight Technologies: 4980A). The measurement voltage was 0.5 Vrms, and the measurement frequency was 10 kHz. The relative permittivity was calculated for a parallel-plate capacitor form by using the static capacitance, the electrode area, and the film thickness which were obtained. In regard to the film thickness, a cut surface of the dielectric thin-film element was worked after measurement by using an FIB (manufactured by FEI: Nova 200), was observed, and was measured.

In order to check the relationship between the degree of the (001) orientation and the relative permittivity of the BaTi₂O₅ thin film, the inventors prepared a plurality of samples having different degrees of the (001) orientation and obtained the relative permittivity of each sample. The table in FIG. 4 shows the results. The samples having a degree of the (001) orientation of 70% or higher were determined as Examples which were oriented toward a (001) crystal axis, and the samples having a degree of the (001) orientation less than 70% were determined as comparative examples which were not oriented toward the (001) crystal axis.

In Example 1 of the BaTi₂O₅ thin film formed under the condition of an oxygen pressure of 1×10⁻⁴ Pa, the degree of the (001) orientation was 97% and the relative permittivity was 1,979. In Example 2 of the BaTi₂O₅ thin film formed under the condition of an oxygen pressure of 1×10⁻³ Pa, the degree of the (001) orientation was 100% and the relative permittivity was 2,153. In Example 3 of the BaTi₂O₅ thin film formed under the condition of an oxygen pressure of 1×10⁻² Pa, the degree of the (001) orientation was 91% and the relative permittivity was 2,066. In Example 4 of the BaTi₂O₅ thin film formed under the condition of an oxygen pressure of 0.1 Pa, the degree of the (001) orientation was 70% and the relative permittivity was 1,595.

In addition, in Comparative Example 1 of the BaTi₂O₅ thin film formed under the condition of an oxygen pressure of 1 Pa, the degree of the (001) orientation was 56% and the relative permittivity was 1,490.

From the foregoing experimental results, it was confirmed that a BaTi₂O₅ thin film having a high relative permittivity (having a relative permittivity of 1,500 or higher) could be obtained in Examples 1 to 4 which were oriented toward a (001) plane, and it was confirmed that a BaTi₂O₅ thin film having a low relative permittivity (having a relative permittivity less than 1,500) could be obtained in the comparative example 1 which was not oriented toward the (001) plane. Particularly, it was confirmed that a BaTi₂O₅ thin film having an extremely high permittivity (having a relative permittivity exceeding 2,000) could be obtained in Example 2 in which the degree of the (001) orientation was 100%.

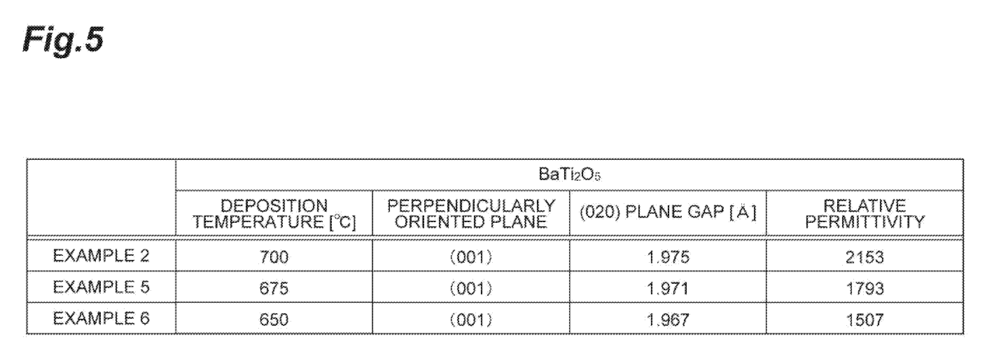

In addition, in order to check the relationship between the (020) plane gap ((020) lattice constant) and the relative permittivity of BaTi₂O₅, the inventors prepared a plurality of samples having different the (020) plane gaps and obtained the relative permittivity of each sample. The table in FIG. 5 shows the results.

As Example 2 in FIG. 5 corresponding to Example 2 in FIG. 4 described above, in the BaTi₂O₅ thin film formed under the condition of a deposition temperature of 700° C., the (020) plane gap was 1.975 Å and the relative permittivity was 2,153. In Example 5 of the BaTi₂O₅ thin film formed under the condition of a deposition temperature of 675° C., the (020) plane gap was 1.971 Å and the relative permittivity was 1,793. In Example 6 of the BaTi₂O₅ thin film fainted under the condition of a deposition temperature of 650° C., the (020) plane gap was 1.967 Å and the relative permittivity was 1,507.

From the foregoing experimental results, it was confirmed that a BaTi₂O₅ thin film having a (020) plane gap of 1.967 Å or larger and a high permittivity (having a relative permittivity of 1,500 or higher) could be obtained in all of Examples 2, 5, and 6. In Examples 2, 5, and 6, it was assumed that since the (020) plane gap was larger than the (020) plane gap of BaTi₂O₅ in a form of single crystal by approximately 0.4%, spontaneous polarization increased and the relative permittivity rose. In addition, from the foregoing experimental results, it was also confirmed that the dielectric constant of the BaTi₂O₅ thin film increased as the (020) plane gap extended.

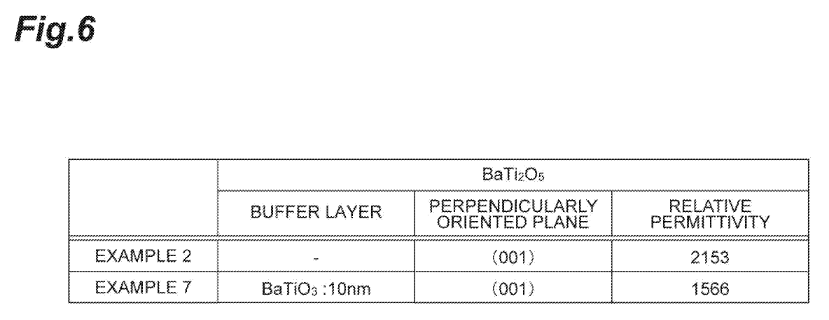

Moreover, in order to check the relationship between the presence or absence of a buffer layer, and the relative permittivity, the inventors prepared samples provided with no buffer layer and samples provided with a buffer layer and obtained the relative permittivity of each sample. The table in FIG. 6 shows the results.

In Example 2 in FIG. 6 that corresponds Example 2 in FIGS. 4 and 5, the BaTi₂O₅ thin film was formed without using a buffer layer, the relative permittivity was 2,153. On the other hand, in Example 7 of the BaTi₂O₅ thin film formed using a BaTiO₃ buffer layer (thickness of 10 nm), the relative permittivity was 1,566.

From the foregoing experimental results, it was confirmed that a BaTi₂O₅ thin film having a high permittivity (having a relative permittivity of 1,500 or higher) could be obtained in all of Examples 2 and 7.

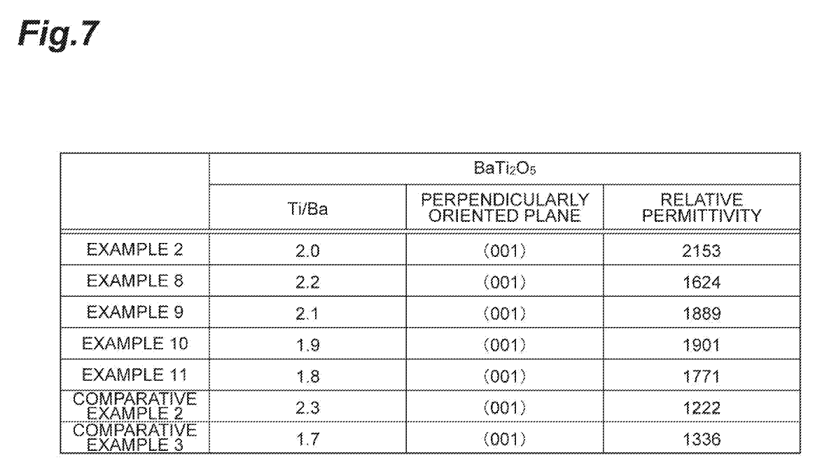

In addition, in order to check the relationship between the mole ratio of Ti to Ba (Ti/Ba mole ratio) and the relative permittivity in the dielectric thin film, the inventors prepared a plurality of samples having different Ti/Ba mole ratios and obtained the relative permittivity of each sample. The table in FIG. 7 shows the results.

As Example 2 in FIG. 7 corresponding to Example 2 in FIGS. 4, 5, and 6 described above, in the BaTi₂O₅ thin film having a Ti/Ba mole ratio of 2.0, the relative permittivity was 2,153. In the BaTi₂O₅ thin film according to Example 8 having a Ti/Ba mole ratio of 2.2, the relative permittivity was 1,624. In the BaTi₂O₅ thin film according to Example 9 having a Ti/Ba mole ratio of 2.1, the relative permittivity was 1,889. In the BaTi₂O₅ thin film according to Example 10 having a Ti/Ba mole ratio of 1.9, the relative permittivity was 1,901. In the BaTi₂O₅ thin film according to Example 11 having a Ti/Ba mole ratio of 1.8, the relative permittivity was 1,771.

In addition, in the BaTi₂O₅ thin film according to a comparative example 2 having a Ti/Ba mole ratio of 2.3, the relative permittivity was 12,222. In the BaTi₂O₅ thin film according to a comparative example 3 having a Ti/Ba mole ratio 1.7, the relative permittivity was 1,336.

From the foregoing experimental results, it was confirmed that a BaTi₂O₅ thin film having a high permittivity (having a relative permittivity of 1,500 or higher) could be obtained in Examples 2, 8 to 11 in which the Ti/Ba mole ratio was within the range of 1.8 to 2.2, and a BaTi₂O₅ thin film having a low permittivity (having a relative permittivity less than 1,500) could be obtained in the comparative examples 2 and 3 in which the Ti/Ba mole ratio was beyond the range of 1.8 to 2.2. Particularly, it was confirmed that a BaTi₂O₅ thin film having an extremely high permittivity (having a relative permittivity exceeding 2,000) could be obtained in Example 2 having a Ti/Ba mole ratio of 2.0.

Hereinabove, an embodiment of the present disclosure has been described. However, the present disclosure is not limited to the foregoing embodiment, and various changes can be made. For example, the dielectric thin-film element is not limited to the thin-film capacitor described above, and a static capacitance thin-film sensor or the like may be adopted.

What is claimed is:

1. A dielectric thin-film element having a lamination structure including:
a first thin-film electrode;
a dielectric thin film laminated on the first thin-film electrode and including BaTi₂O₅ as a main composition; and
a second thin-film electrode laminated on the dielectric thin film,
wherein a {001} plane of BaTi₂O₅ in the dielectric thin film is oriented in a lamination direction of the lamination structure.

2. The dielectric thin-film element according to claim 1,
wherein in the dielectric thin film, a gap between (020) planes of BaTi₂O₅ present within a plane perpendicular to the lamination direction is 1.967 Å or larger.

3. The dielectric thin-film element according to claim 1, further comprising:
a buffer layer interposed between the first thin-film electrode and the dielectric thin film.

4. The dielectric thin-film element according to claim 3,
wherein the buffer layer is made of BaTiO₃.

5. The dielectric thin-film element according to claim 1,
wherein a mole ratio Ti/Ba of Ti to Ba included in the dielectric thin film is within a range of 1.8 to 2.2.

6. The dielectric thin-film element according to claim 1,
wherein a part of Ba of BaTi₂O₅ in the dielectric thin film is replaced with at least one element of the group consisting of Mg, Ca, and Sr.

7. The dielectric thin-film element according to claim 1,
wherein a part of Ti of BaTi₂O₅ in the dielectric thin film is replaced with Zr.

8. An electronic component comprising:
the dielectric thin-film element according to claim 1.
